(19) United States
(12) Patent Application Publication
(10) Pub. No.: US 2019/0104623 A1
(43) Pub. Date: Apr. 4, 2019

(54) MOBILE DEVICE ENGAGEMENT APPARATUS

(71) Applicant: Dale C. BACKUS, Apex, NC (US)

(72) Inventor: Dale C. BACKUS, Apex, NC (US)

(21) Appl. No.: 16/149,035

(22) Filed: Oct. 1, 2018

Related U.S. Application Data
(60) Provisional application No. 62/566,270, filed on Sep. 29, 2017.

(51) Int. Cl. H05K 5/02; F16B 1/00; F16B 2/20

(52) U.S. Cl. CPC H05K 5/0204; F16B 2001/0035; F16B 2/205; F16B 1/00

(57) ABSTRACT

A mobile device engagement apparatus may include an engagement housing member that extends from a first end to an opposing second end and defines an engagement element cavity. The apparatus may an engagement element that extends from a first engagement element end to an opposing second engagement element end. The engagement element may be moveable between at least one of a stored configuration, an operating configuration, and a secured configuration. The apparatus includes a connecting element configured to securely engage the engagement housing member and the engagement element with another. The connecting element may provide for the rotation of the engagement element with respect to the engagement housing member.

### CROSS-REFERENCE TO RELATED APPLICATION(S)

To the full extent permitted by law, the present U.S. Non-Provisional patent application hereby claims priority to and the full benefit of U.S. Provisional Application Ser. No. 62/566,270, filed Sep. 29, 2017, the disclosure of which is each incorporated herein by reference in its entirety.

### FIELD OF THE INVENTION

The present disclosure generally relates to a mobile device engagement apparatus, and more specifically, to a mobile device engagement apparatus configured to provide for handling and securing a mobile device to a desired location, such as, for example, a user's finger. The mobile device engagement apparatus may further be configured to provide for securely positioning the mobile device in a desired position for viewing ease.

### BACKGROUND

Generally speaking, mobile device cases and such have been used to protect mobile devices from damage. Other mobile device cases have also been used to position mobile devices on tables for viewing content on the mobile device using, for example, a kickstand that extends from the mobile device using a hinged extension bar. Additionally, some mobile device cases have been used to secure a mobile device to a person with, such as, handheld elastic straps, grips, and the like. These mobile device cases have been problematic by adding additional bulk, weight, and increased dimensions. Additionally, mobile device cases with kickstand extensions suffer from repetitive usage which can lead to mechanical failure of the hinged connection.

Therefore, a need exists for a suitable mobile device engagement apparatus that provides for reliably and continued positioning of the mobile device on a surface. Further, a need exists for a mobile device engagement apparatus that provides for securing the mobile device to the user when holding the mobile device.

### BRIEF SUMMARY

Example implementations of the present disclosure are directed to a mobile device engagement apparatus. In some aspects, the mobile device engagement apparatus may include an engagement housing member. The engagement housing member may extend from a first end to an opposing second end. In some aspects, the engagement housing member may define an engagement element cavity. The mobile device engagement apparatus may further include an engagement element. According to some aspects, the engagement element may extend from a first engagement element end to an opposing second engagement element end. The engagement element may be moveable between at least one of a stored configuration, an operating configuration, and a secured configuration. The mobile device engagement apparatus may further include a connecting element configured to securely engage the engagement housing member and the engagement element with another and/or securely engage the engagement housing member to the engagement element. The connecting element may be further configured to provide for the rotation of the engagement element with respect to the engagement housing member.

According to some aspects, the engagement element may further include an engagement member and a protective member. Additionally, the engagement element may further include a securing apparatus that may be configured to retain the engagement element in the secured configuration.

In some aspects, the engagement element may be configured to provide an opposing force that biases the engagement element to the operating configuration as the engagement element is manipulated from the operating configuration to the secured configuration. Additionally and/or alternatively, the opposing force may further provide for retaining the engagement element in the secured configuration when the securing apparatus is operably engaged.

According to some aspects of the present disclosure, the mobile device engagement apparatus may further include a base member that may extend from a first base end to an opposing second base end. In some aspects, the base member may be further configured to operably engage the engagement housing member. Additionally, the base member and the engagement housing member may be configured to move with respect to one another when the base member of the mobile device engagement apparatus is securely engaged with a mobile device.

According to some aspects, the engagement housing member may further include a base engagement element that extends from the engagement housing member. The base member may further define a base channel configured to reciprocally engage the base engagement element that extends from the engagement housing member. In some aspects, the engagement housing member may be configured to move with respect to the base member along a longitudinal axis that extends from the first end to the opposing second end of the mobile device engagement apparatus.

According to some aspects, the mobile device engagement apparatus may further include a magnetic element configured to removably attach the mobile device engagement apparatus to a magnetic surface. In one aspect, the engagement housing member may further define a top surface that may include a material configured to operably engage a surface so as to affix the mobile device engagement apparatus to the surface.

According to some aspects, a method of engaging a mobile device engagement apparatus may be provided. In some aspects, the method may include providing a force to an engagement element of a mobile device engagement apparatus so as to transform the mobile device engagement apparatus from a stored configuration to an operating configuration. The mobile device engagement apparatus may include an engagement housing member that extends from a first end to an opposing second end. The engagement housing member may define an engagement element cavity. The mobile device engagement apparatus may include an engagement element extending from a first engagement element end to an opposing second engagement element end. The engagement element may be moveable between at least one of the stored configuration, the operating configuration, and a secured configuration. The mobile device engagement apparatus may include a connecting element configured to securely engage the engagement housing member and the engagement element with another. The connecting element may be further configured to provide for the rotation of the engagement element with respect to the engagement housing member.

In some aspects, the method may further include providing a first force to the first engagement element end and an opposing second force to the opposing second engagement element end so as to bias the first engagement element end and the opposing second engagement element end towards one another.

According to some aspects, the method may further include engaging a securing apparatus of the engagement element so as to position the mobile device engagement apparatus in the secured configuration. The securing apparatus may be configured to retain the engagement element in the secured configuration.

The foregoing illustrative summary, as well as other exemplary objectives and/or advantages of the invention, and the manner in which the same are accomplished, are further explained within the following detailed description and its accompanying drawings.

### BRIEF DESCRIPTION OF THE DRAWINGS

The present disclosure will be better understood by reading the Detailed Description with reference to the accompanying drawings, which are not necessarily drawn to scale, and in which like reference numerals denote similar structure and refer to like elements throughout, and in which:

FIG. 1 illustrates a top perspective view of a mobile device engagement apparatus having an engagement element disposed in a stored configuration according to one example aspect of the present disclosure;

FIG. 2 illustrates a bottom perspective view of a mobile device engagement apparatus according to one example aspect of the present disclosure;

FIG. 3 illustrates top view of a mobile device engagement apparatus according to one example aspect of the present disclosure;

FIG. 4 illustrates a side view of a mobile device engagement apparatus according to one example aspect of the present disclosure;

FIG. 5 illustrates a cross-sectional side view taken along line A of the mobile device engagement apparatus of FIG. 3 according to one example aspect of the present disclosure;

FIG. 6 illustrates a zoomed view of a cross-sectional side view of the engagement mobile device mount taken from box B of FIG. 5 showing a connecting element in further detail according to one aspect of the present disclosure;

FIG. 7 illustrates a top perspective view of a mobile device engagement apparatus having an engagement element disposed in an operating configuration according to one example aspect of the present disclosure;

FIG. 8 illustrates a top perspective view of an engagement element disposed in an operating configuration and rotated with respect to an engagement housing member of a mobile device engagement apparatus according to one example aspect of the present disclosure;

FIG. 9 illustrates a top perspective view of an engagement element disposed in a secured configuration according to one example aspect of the present disclosure;

FIG. 10 illustrates a top perspective view of an engagement element disposed in a secured configuration and rotated with respect to an engagement housing member of a mobile device engagement apparatus according to one example aspect of the present disclosure;

FIG. 11 illustrates a cross-sectional side view of an engagement element disposed in a secured configuration of a mobile device engagement apparatus according to one example aspect of the present disclosure;

FIG. 12 illustrates a zoomed view of a cross-sectional side view of the mobile device engagement apparatus taken from box D of FIG. 11 showing a securing apparatus in further detail according to one aspect of the present disclosure;

FIG. 13 illustrates a zoomed view of a top perspective view of the mobile device engagement apparatus taken from box C of FIG. 9 showing a securing apparatus in further detail according to one aspect of the present disclosure;

FIG. 14 illustrates a top view of a mobile device engagement apparatus according to one example aspect of the present disclosure;

FIG. 15 illustrates a bottom view of an engagement housing member of a mobile device engagement apparatus according to one example aspect of the present disclosure;

FIG. 16 illustrates a bottom perspective view of a mobile device engagement apparatus according to one example aspect of the present disclosure;

FIG. 17 illustrates a bottom perspective view of an engagement housing member of a mobile device engagement apparatus according to one example aspect of the present disclosure;

FIG. 18 illustrates a side view of a mobile device engagement apparatus according to one example aspect of the present disclosure;

FIG. 19 illustrates a perspective view of a mobile device engagement apparatus with an engagement element disposed in a secured configuration according to one example aspect of the present disclosure;

FIG. 20 illustrates a side view of a mobile device engagement apparatus with an engagement element disposed in an operating configuration according to one example aspect of the present disclosure;

FIG. 21 illustrates a perspective view of a mobile device engagement apparatus with an engagement element disposed in an operating configuration according to one example aspect of the present disclosure; and

FIG. 22 illustrates a schematic block diagram for a method of engaging a mobile device engagement apparatus according to one example aspect of the present disclosure.

It is to be noted that the drawings presented are intended solely for the purpose of illustration and that they are, therefore, neither desired nor intended to limit the disclosure to any or all of the exact details of construction shown, except insofar as they may be deemed essential to the claimed disclosure.

### DETAILED DESCRIPTION

Some implementations of the present disclosure will now be described more fully hereinafter with reference to the accompanying drawings, in which some, but not all implementations of the disclosure are shown. Indeed, various implementations of the disclosure may be expressed in many different forms and should not be construed as limited to the implementations set forth herein; rather, these exemplary implementations are provided so that this disclosure will be thorough and complete, and will fully convey the scope of the disclosure to those skilled in the art. As used herein, the term “and/or” and the “/” symbol includes any and all combinations of one or more of the associated listed items. Further, unless otherwise indicated, something being described as being a first, second or the like should not be construed to imply a particular order. It should be understood that the terms first, second, etc. may be used herein to describe various steps, calculations, positions and/or the like, these steps, calculations or positions should not be limited to these terms. These terms are only used to distinguish one operation, calculation, or position from another. For example, a first position may be termed a second position, and, similarly, a second step may be termed a first step, without departing from the scope of this disclosure. Additionally, something may be described as being above something else (unless otherwise indicated) may instead be below, and vice versa; and similarly, something described as being to the left of something else may instead be to the right, and vice versa. As used in the specification, and in the appended claims, the singular forms “a”, “an”, “the”, include plural referents unless the context clearly dictates otherwise. Like reference numerals refer to like elements throughout.

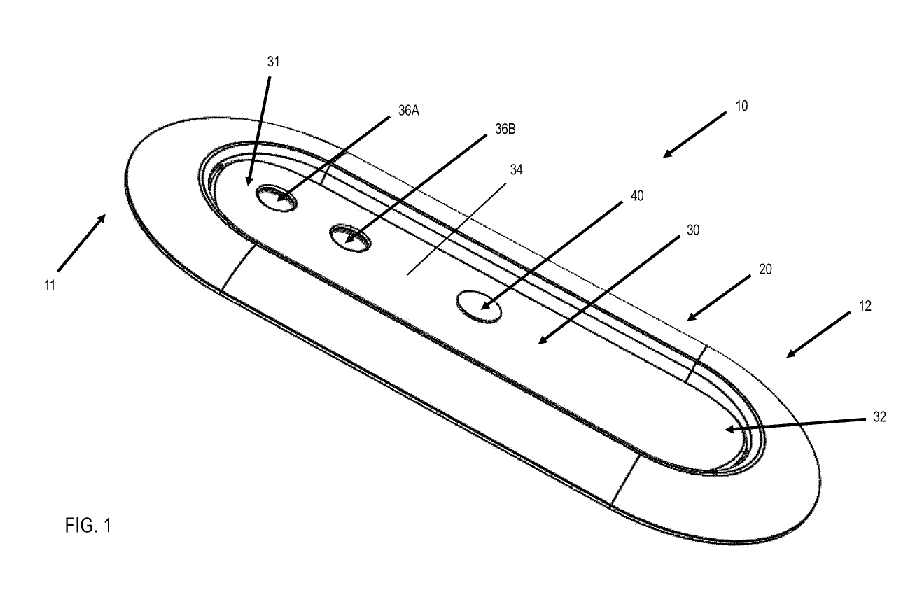

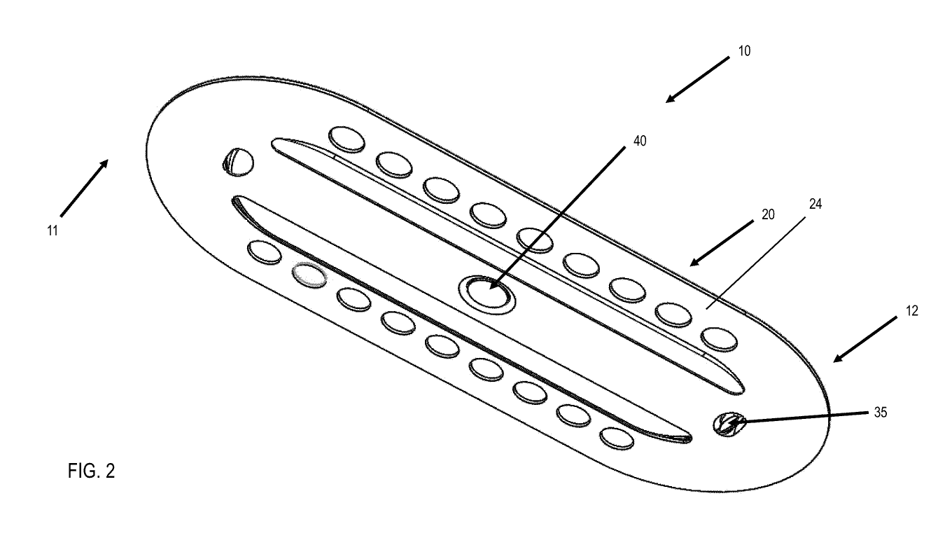

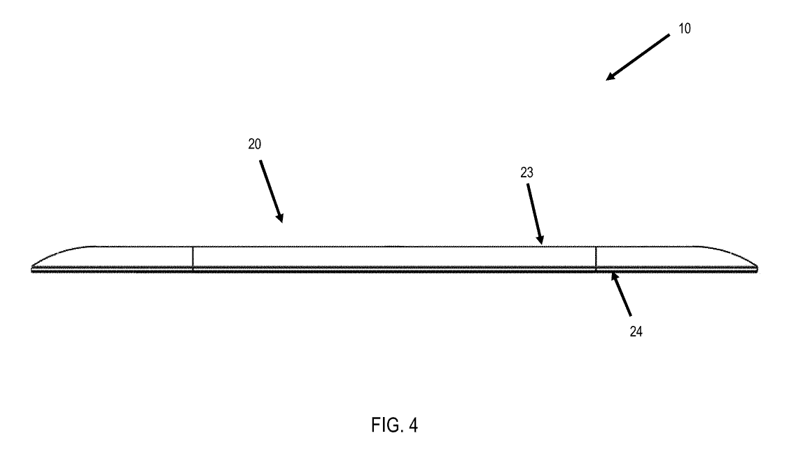

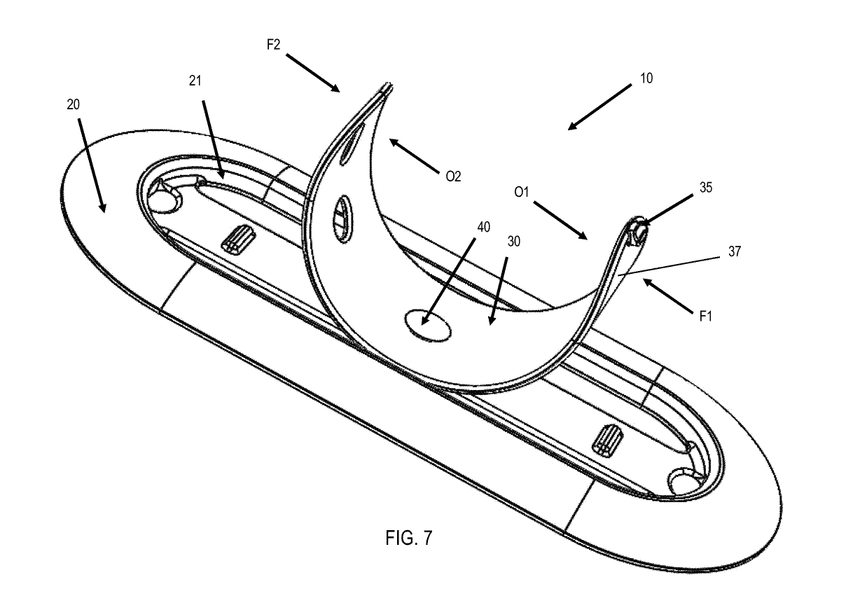

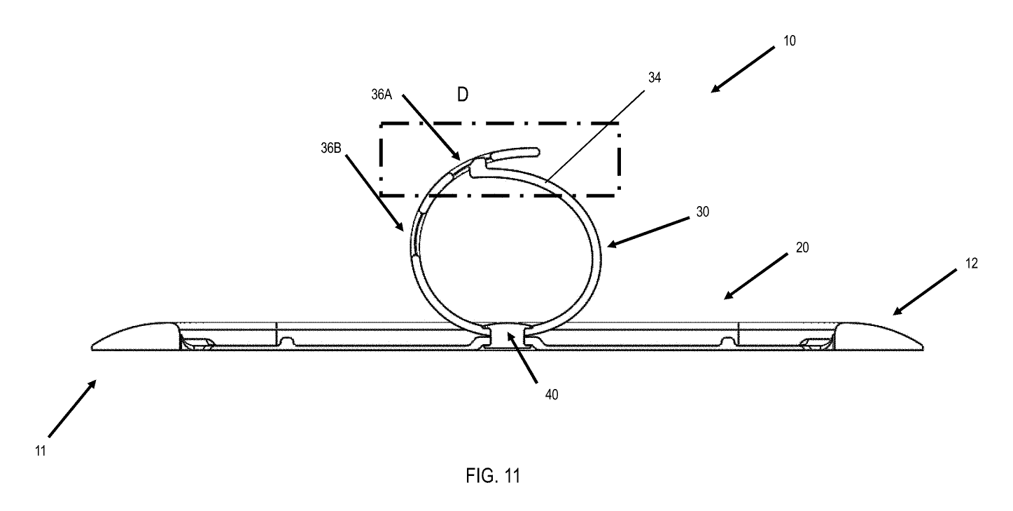

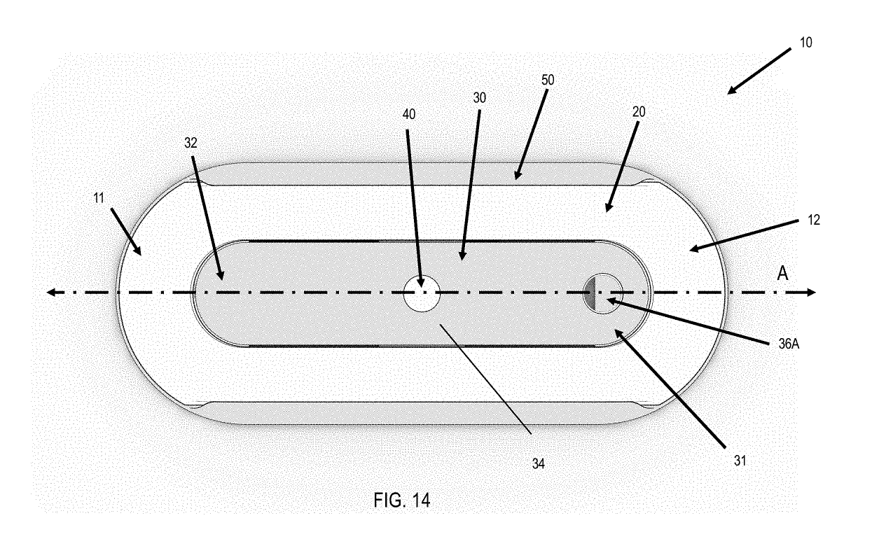

Implementations of the present disclosure provide for a mobile device engagement apparatus as shown in FIGS. 1 and 14. According to some aspects of the present disclosure, a mobile device engagement apparatus 10, as shown in FIG. 1, may provide for the engagement of a mobile device, mobile device case, and/or the like with a user, object, surface, and/or the like. For example, the mobile device engagement apparatus 10 may include an engagement housing member 20 that extends from the first end 11 to the opposing second end 12. As shown in FIG. 7, the engagement housing member 20 may further define an engagement element cavity 21, as shown in FIGS. 1, 3, 5, 7, and 8-11. In some aspects, the engagement element cavity 21 may be configured to receive an engagement element 30 therein. The engagement housing member may include at least one top surface 23, as shown in FIGS. 1, 3 and 4, and at least one bottom surface 24, as shown in FIGS. 2 and 4.

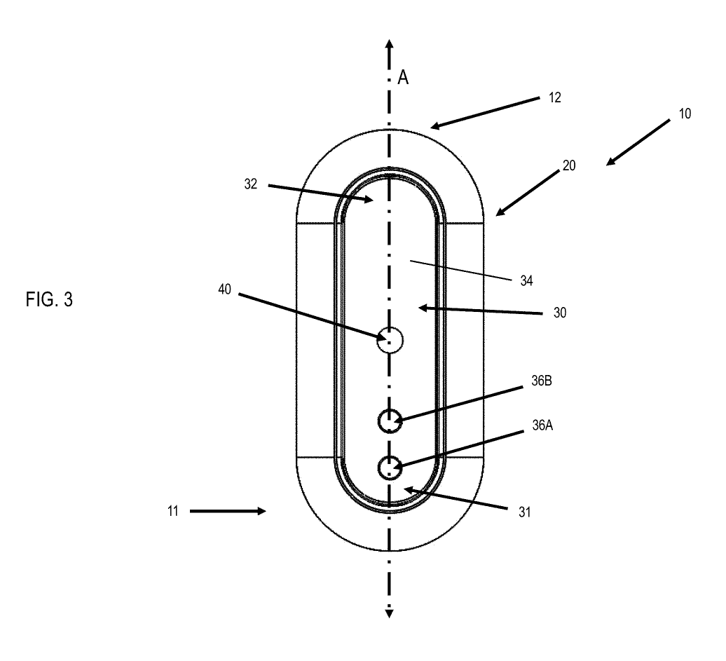

Referring to FIG. 1, the mobile device engagement apparatus 10 may also include an engagement element 30. The engagement element 30 may extend from a first engagement element end 31 to an opposing second engagement element end 32. As shown in FIG. 3, the first end and opposing second end 11, 12 of the mobile device engagement apparatus 10 may define a longitudinal axis A. According to some aspects, when the engagement element 30 is disposed in the stored configuration, the first engagement element end 31 and the opposing second engagement element end 32 may define an axis that extends parallel to and/or colinear with the longitudinal axis A of the mobile device engagement apparatus 10.

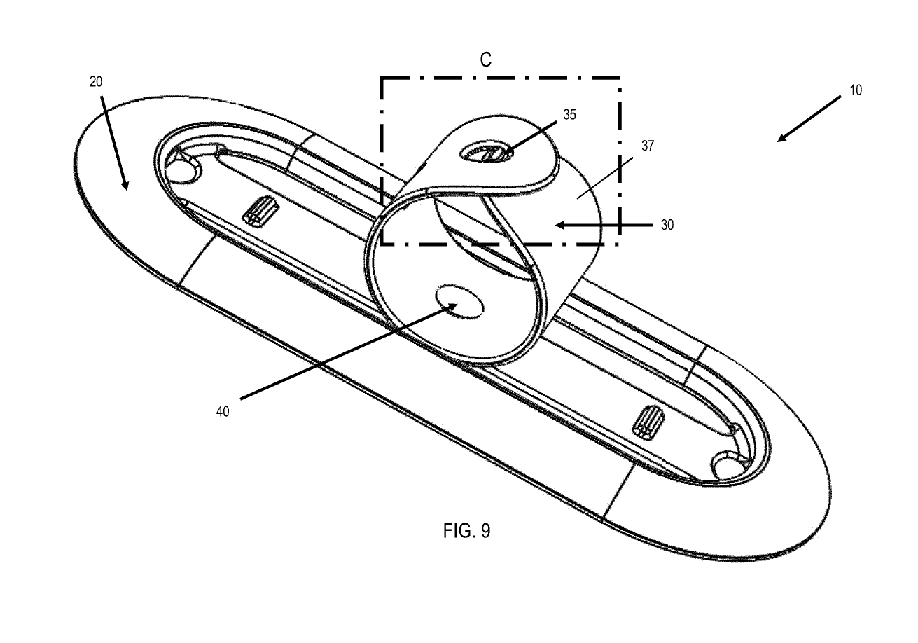

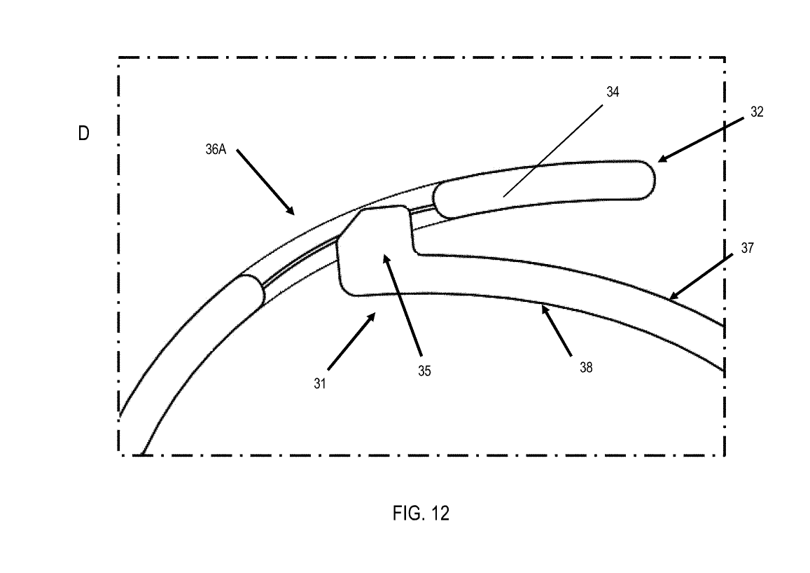

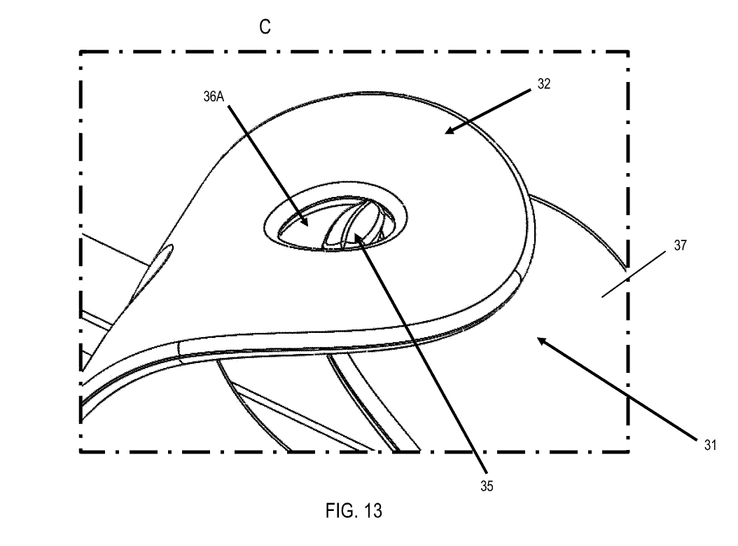

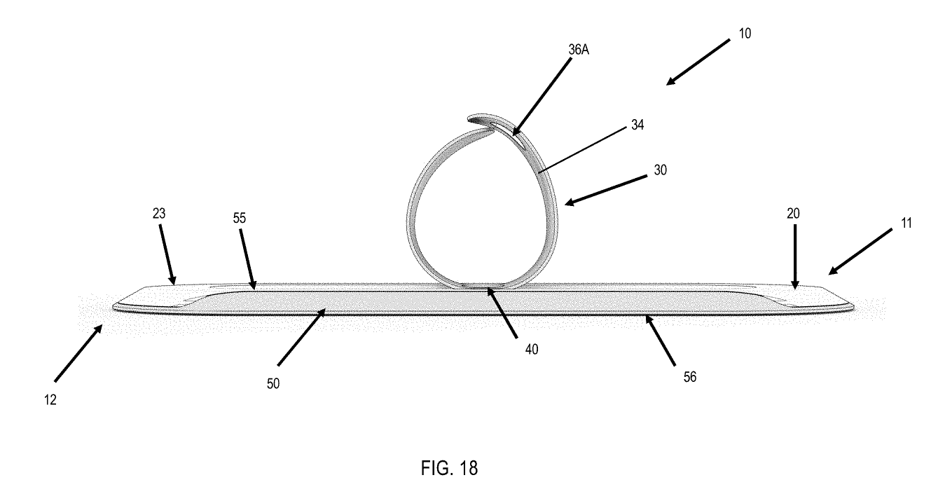

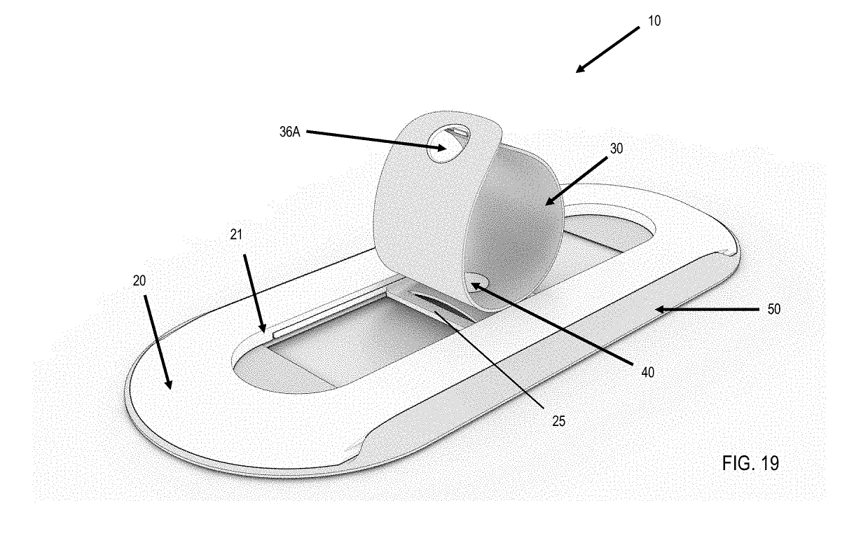

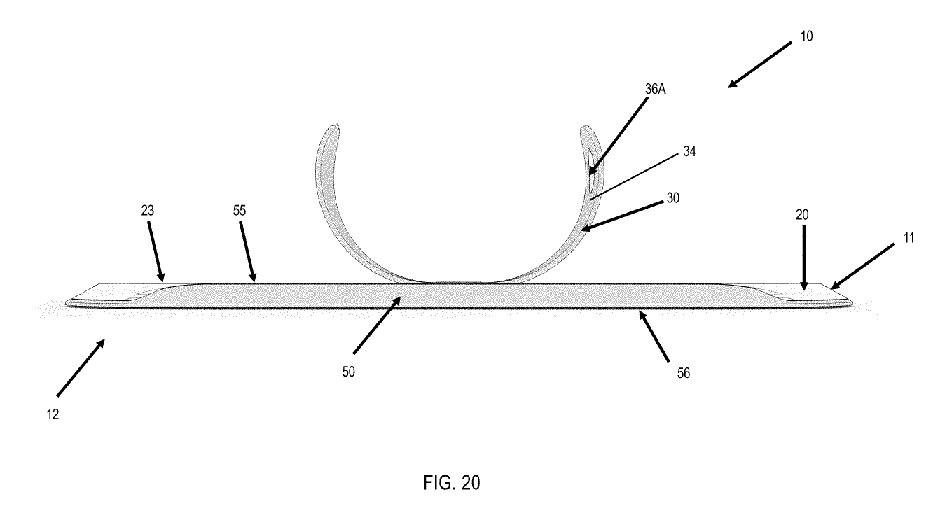

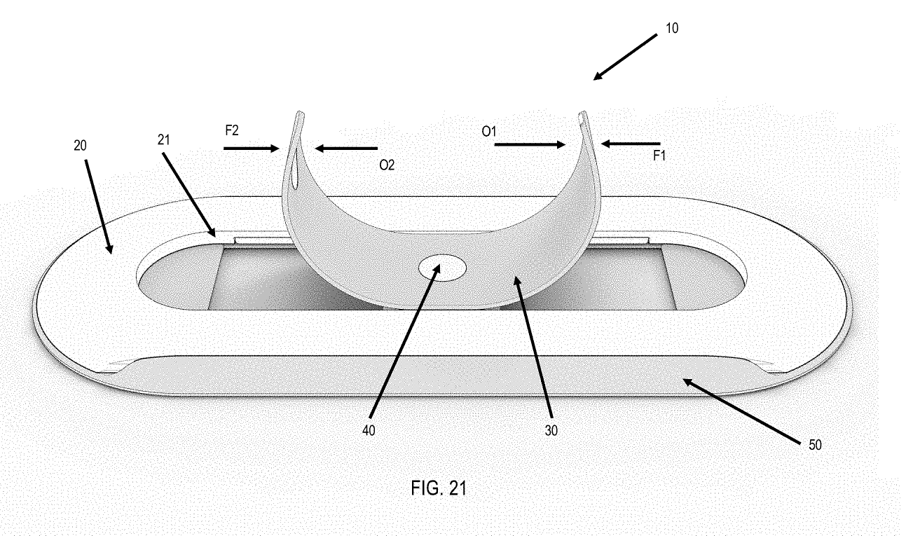

According to some aspects, the engagement element 30 may be moveable between at least one of a stored configuration, an operating configuration, and/or a secured configuration. Referring to FIGS. 1, 3, 4, 5, and 14, the engagement element 30 may be disposed within the engagement element cavity 21 when the mobile device engagement apparatus 10 is positioned in the stored configuration. In particular, the engagement element 30 may provide a minimal height profile when the engagement element 30 is disposed in the stored configuration. In some aspects, when the engagement element 30 is disposed in the operating configuration, as shown in FIGS. 7, 8, 20 and 21, the mobile device engagement apparatus 10 may be propped, angled, or placed on a surface for convenient viewing. The first engagement element end 31 and the second engagement element end 32 may extend from the engagement housing member 20 to provide support for positioning the mobile device in an upright fashion when placed on a surface. Additionally or alternatively, when the engagement element 30 is disposed in the secured configuration, as shown in FIGS. 9, 10, 11, 12, 13, 18, and 19, the engagement element 30 may form a closed loop configured to receive at least one body portion of a user therethrough so as to allow a user to securely grasp a mobile device with the mobile device engagement apparatus.

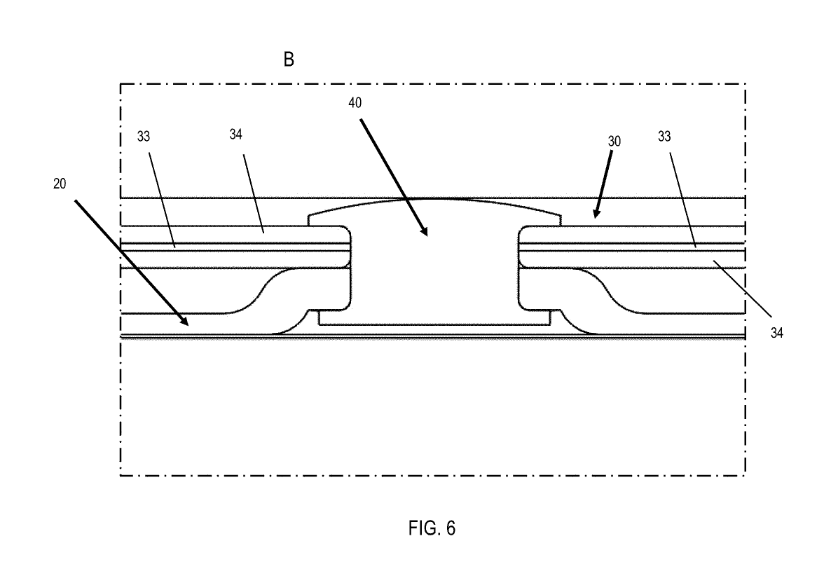

Referring to FIGS. 1, 5, and 6, the mobile device engagement apparatus 10 may further include a connecting member 40 configured to securely engage the engagement housing member 20 and the engagement element 30 with one another. In some aspects, the connecting member 40 may be configured to provide for rotation of the engagement element 30 with respect to the engagement housing member 20. As shown in FIG. 6, the connecting member 40 may define a cylindrical flange configured to engage respective apertures defined by the engagement housing member 20 and the engagement element 30. An inner cylindrical portion of the connecting member 40 allows for the free rotation of the engagement element 30 with respect to the engagement housing member 20. Additionally or alternatively, the cylindrical flange portions of the connecting member 40 prevent vertical and/or lateral movement of the engagement element 30 with respect to the engagement housing member 20.

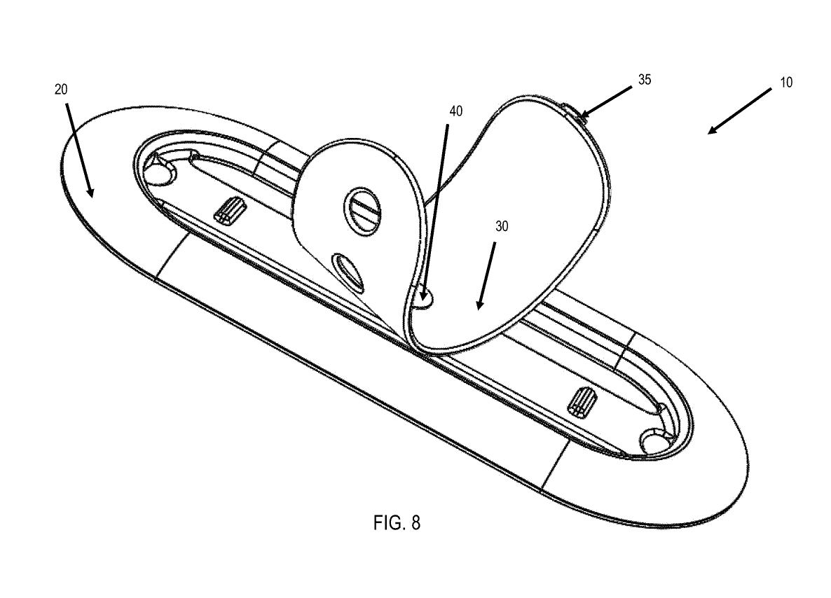

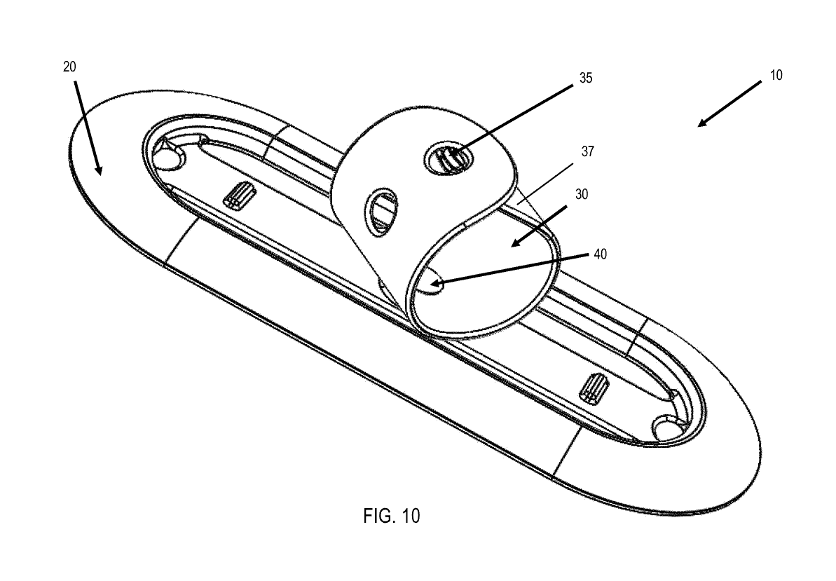

For example, the engagement element may define a connecting element aperture configured to receive the connecting element therethrough. Likewise, the engagement housing member may define a similar aperture configured to receive the connecting element therethrough. Additionally, the connecting element may be configured to operably engage the connecting element aperture defined by the engagement element so as to provide for the rotation of the engagement element with respect to the engagement housing member of the mobile device engagement apparatus, as shown in FIGS. 8 and 10.

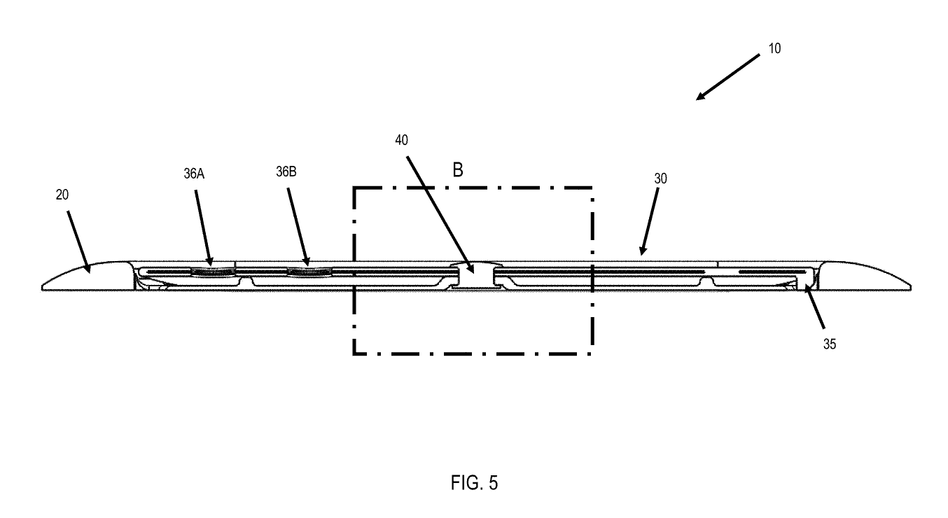

In some aspects, the engagement element 30 may include an engagement member 33 and a protective member 34, as shown in FIGS. 5 and 6. The engagement member 33, which may be semi-rigid and/or configured to be manipulated from a stored configuration (i.e., substantially planar form and within the cavity 21 defined by the engagement housing member 20 of the mobile device engagement apparatus 10, as shown in FIGS. 1, 4 and 5) to an operating configuration (i.e., substantially curved and/or concave form and extending from the engagement element cavity 21, as shown in FIGS. 7 and 8).

Additionally or alternatively, the engagement member 33 may be configured as a bi-stable element (e.g., an element configured to be at rest in two separate and distinct equilibrium states). As such, the engagement member 33 may be manipulated from the stored configuration to the operating configuration by applying a force to at least one portion of the engagement element 30 thereby causing the engagement member 33 to move from the first equilibrium state (e.g., the stored configuration) to the second equilibrium state (e.g., the operating configuration), and remain in the second equilibrium state.

In some aspects, when the engagement member 33 is disposed in the operating configuration (i.e., the first equilibrium state), a user may apply a force to at least one portion of the engagement element 30 to cause the engagement element to revert to the stored configuration (i.e., the second equilibrium state). Further, as the engagement member 33 may be configured as a bi-stable element, when a user attempts to bring the first and opposing second end 31, 32 of the engagement element 30 towards each other to position the engagement element 30 in the secured configuration, as shown, for example in FIG. 9, from the operating configuration, as shown, for example, in FIG. 7, the engagement element 30 may be configured to resist the user's force input F1, F2 by providing an opposing force O1, O2 that biases the engagement element 30 toward the operating configuration.

Referring to FIGS. 1, 5, and 6, the engagement element 30 may include a protective member 34, which may incorporate and/or include a protective material (e.g., a polymer or protective coating) that is flexible enough to conform to the movements of the engagement member 33. Additionally or alternatively, the protective material may have a static and/or kinetic frictional coefficient that is sufficient to provide for the protective member 34 to engage a surface and/or another portion of the protective member so as to limit the movement of the engagement element 30. In some aspects, the protective member 34 may fully encapsulate the engagement member 33. Alternatively, the protective member may cover a portion of the engagement member 33.

Referring to FIGS. 1, 5, 7, 9, 11, and 12, the mobile device engagement apparatus 10 may include an engagement element 30 that includes a securing apparatus 35 configured to retain the engagement element 30 in the secured configuration. As shown in FIG. 1, the engagement element 30 may define at least one securing aperture 36A, 36B that extends vertically through the engagement element 30. In some aspects, the at least one securing apertures 36A, 36B may be disposed proximate one of the first end 31 and/or opposing second end 32 of the engagement element 30, while the securing apparatus 35 may be disposed proximate at least on the other of the first end 31 and opposing second end 32 of the engagement element 30. In some aspects, the securing apparatus 35 may be disposed proximate the opposing second end 32 of the engagement element 30 and further, may extend orthogonally, and in some aspects, downwardly from the engagement element 30 when the engagement element 30 is disposed in the stored configuration, as shown in FIG. 5. According to some aspects, when the engagement element 30 is disposed in the operating configuration, as shown in FIG. 7 and/or in the secured configuration, as shown in FIGS. 9, and 11-13, the securing apparatus 35 may extend orthogonally from a portion of the bottom surface 37 of the engagement element 30.

Referring to FIGS. 9, and 11-13, when the engagement element 30 is positioned in the secured configuration, the bi-stable nature of the engagement member 33 attempts to bias the engagement element 30 from the unstable nature of the engagement member 33 in the secured configuration toward the stable nature of the engagement member when the engagement member is positioned in the operating configuration. For example, when the engagement element 30 is configured in the secured configuration, the unstable nature of the engagement member 33 provides an opposing force such that the securing apparatus 35 reciprocally engages the at least one securing aperture 36A in a frictional engagement such that the engagement element 30 creates a closed loop. According to some aspects of the present disclosure, when the engagement element is disposed in the secured configuration, the circumference of the engagement element may be substantially similar to the circumference of a user's finger thereby allowing a user to insert their finger through the completed loop defined by the engagement element disposed in the secured configuration.

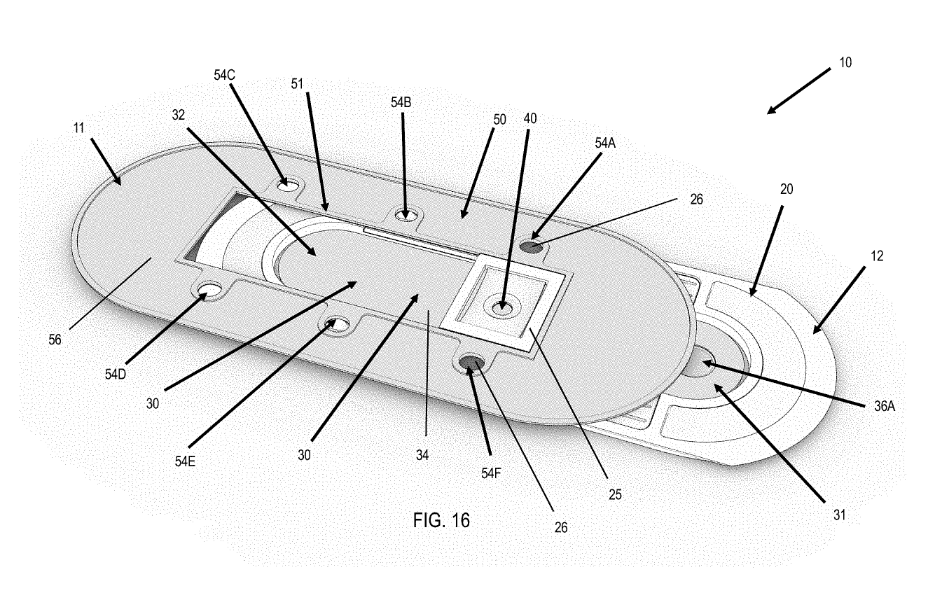

Referring to FIGS. 14 and 16, in some aspects, the mobile device engagement apparatus 10 may further include a base member 50 that extends from a first base end 51 to an opposing second base end 52. According to some aspects, the base member 50 may be configured to operably engage an engagement housing member 20 such that the base member 50 and the engagement housing member 20 move with respect to one another along a longitudinal axis A of the mobile device engagement apparatus 10. Additionally or alternatively, the base member 50 may define a bottom surface 56 configured to securely engage a mobile device. In some aspects, a bottom surface 24 of the engagement housing member 20 may be configured to securely engage a mobile device. For example, at least one of a bottom surface 24, 56 of the engagement housing member 20 and the base member 50 may include a frictional material that has a sufficient frictional coefficient to prevent the engagement housing member and/or base member from moving when the mobile device engagement apparatus 10 is operably engaged with a mobile device. Additionally and/or alternatively, at least one of a bottom surface 24, 56 of the engagement housing member 20 and the base member 50 may include an adhesive material configured to operably engage the mobile device so as to prevent movement of the mobile device engagement apparatus 10 when the mobile device engagement apparatus 10 is operably engaged with the mobile device.

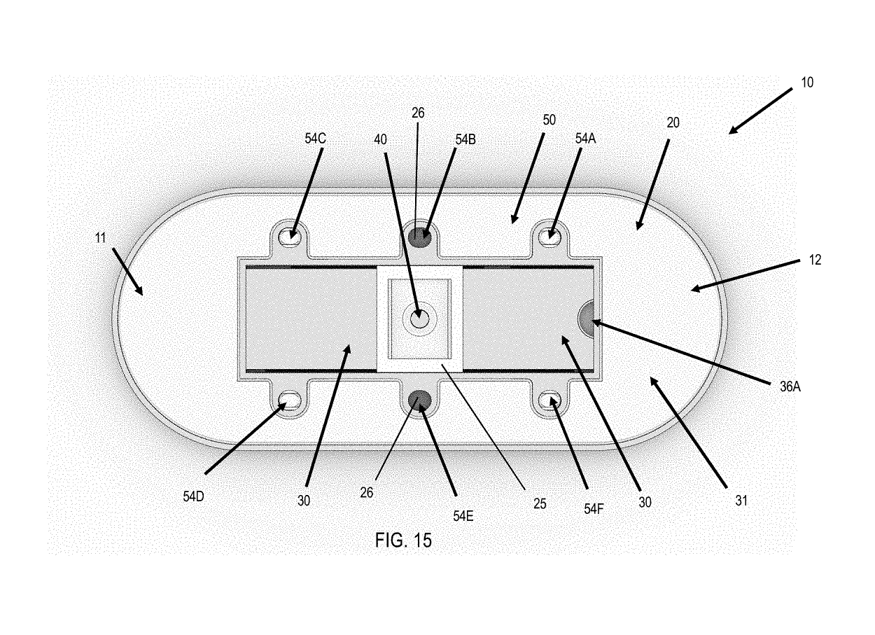

Referring to FIGS. 15-17, the engagement housing member 20 may further include a base engagement element 25 that extends from the engagement housing member 20. In some aspects, the base engagement element 25 may extend orthogonally from the engagement housing member 20 with respect to the longitudinal axis A of the mobile device engagement apparatus 10. According to some aspects, the base engagement element 25 extends vertically downward from a bottom surface 24 of the engagement housing member 20.

Referring to FIG. 16, the base member 50 may further define a base channel 53 that extends longitudinally along the longitudinal axis A of the mobile device engagement apparatus 10. According to some aspects, the base channel 53 of the base member 50 and the base engagement element 25 of the engagement housing member 20 may be configured to reciprocally engage one another. For example, at least a portion of the base engagement element 25 may be configured to slide within and/or engage the base channel 53. In some aspects, the base member 50 may further define a plurality of apertures 54A-E. The at least one aperture 54A may be configured to receive a magnetic element therein configured to magnetically engage a magnetic element 26 of the engagement housing member 20.

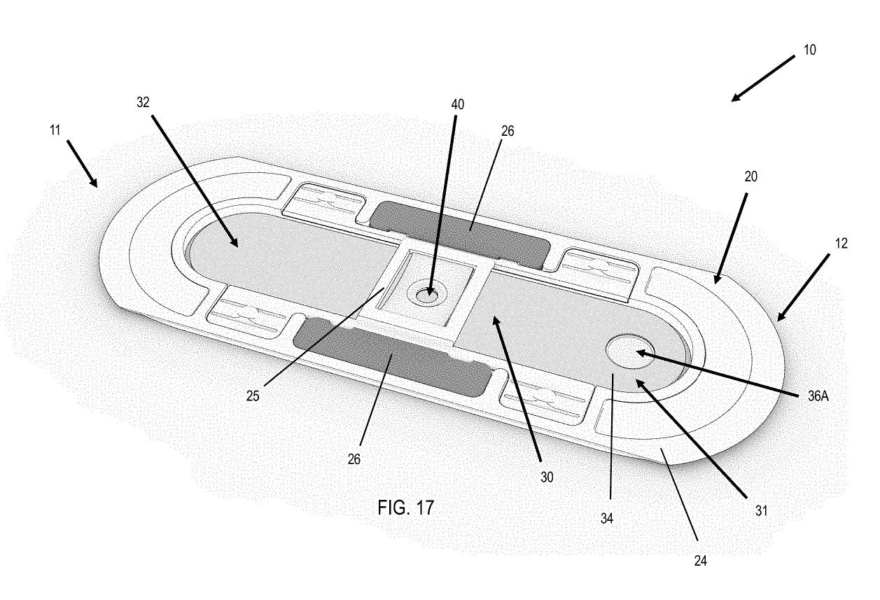

Referring to FIG. 17, according to some aspects, the engagement housing member 20 may include a magnetic element 26. The engagement housing member 20 may be further configured to be magnetically attracted to a mobile device, mobile device case, and/or the like. According to another aspect, as shown in FIG. 3, the bottom surface of the engagement housing member may define at least one aperture, cavity, and/or the like configured to reciprocally engage a magnetic element configured to magnetically engage a mobile device, mobile device case, any magnetically attracted object (e.g., street sign posts, home appliances, magnetic mounting device, etc.), and/or the like. According to some aspects, the magnetic element 26 may be configured to magnetically engage additional magnetic elements within the mobile device engagement apparatus 10, such as, for example, a magnetic element disposed proximate an aperture 54A defined by the base member 50. The magnetic engagement between the magnetic element disposed proximate the aperture 54A defined by the base member 50 and the magnetic element 26 of the engagement housing member 20 may provide for precise translated motion of the engagement housing member 20 with respect to the base member 50 along the longitudinal axis A of the mobile device engagement apparatus 10. In some aspects, a ratcheting mechanism may be used to provide for the longitudinal movement of the engagement housing member 20 with respect to the base member 50 along the longitudinal axis A of the mobile device engagement apparatus 10.

According to some aspects, the base member 50 and/or the engagement housing member 20 may include material configured to operably engage a surface so as to temporarily affix the mobile device engagement apparatus 10 to the surface. For example, referring to FIGS. 3-6, 14, 19, and 21, the engagement housing member 20 may define a top surface 23. In some aspects, the top surface 23 may include a material with a sufficient friction coefficient to operably engage a surface so as to temporarily affix the mobile device engagement apparatus 10 to the surface. According to some aspects, the top surface 23 may include a material configured to provide a plurality of microscopic indentations in the top surface 23 that are configured to provide for the fluid flow into regions of lower ambient pressure.

Additionally or alternatively, the base member 50 may define a top and bottom surface 55, 56. In some aspects, the top and bottom surface 55, 56 of the base member 50 may include a material with a sufficient friction coefficient to operably engage a surface so as to temporarily affix the mobile device engagement apparatus 10 to the surface. According to some aspects, the top and bottom surface 55, 56 of the base member 50 may include a material configured to provide a plurality of microscopic indentations in the top and bottom surface 55, 56 that are configured to provide for the fluid flow into regions of lower ambient pressure.

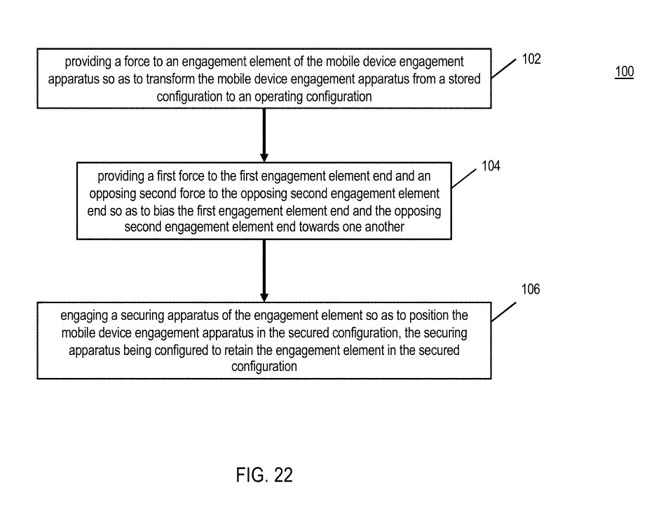

One exemplary aspect of the present disclosure provides for a method of engaging a mobile device engagement apparatus, like those previously discussed herein. For example, FIG. 22 illustrates a schematic block diagram of a method of engaging a mobile device engagement apparatus according to some aspects of the present disclosure. A method of engaging a mobile device engagement apparatus 100 may include providing a force to an engagement element of a mobile device engagement apparatus positioned in the stored configuration 102. A user may provide a force to a portion of the engagement member 33 of the engagement element 30 so as to disturb the engagement member 33 from a first stable nature of the engagement element 30 when disposed in the stored configuration to a second stable nature of the engagement element 30 when the engagement element 30 is arranged in the operating configuration.

The method 100 may further include providing a first force to a first engagement element end and an opposing second force to the opposing second engagement element end so as to bias the first engagement element end and the opposing second engagement element towards one another 104. In some aspects, the method may include providing a first force to one of the first and second engagement element ends 31, 32 and an opposing second force to the other of the first and second engagement element ends 31, 32. In some aspects, the first and opposing second forces may be directed towards each other. For example, as shown in FIG. 7, the first and second opposing forces are directed towards each other. According to some aspects, the method may include providing the first and second forces that are directed towards each other to the first and second engagement element ends respectively so as to bias the engagement member 33 and/or the mobile device engagement apparatus 10 from the operating configuration to a secured configuration. According to another aspect, the first and opposing second forces may be directed away from each other so as to bias the engagement member 33 and/or the mobile device engagement apparatus 10 from the operating configuration to the stored configuration.

According to some aspects, the method 100 may further include engaging a securing apparatus of the engagement element so as to position the mobile device engagement apparatus in a secured configuration 106. For example, the securing apparatus 35 may be positioned proximate at least one of the securing apertures 36A, 36B of the engagement element 30 so as to be in a frictional engagement such that the engagement element 30 creates a closed loop.

In another aspect, the method may include rotating the engagement element 30 with respect to the engagement housing member 20 and/or the base member 50. For example, the connecting element 40 may be configured to provide for the rotation of the engagement element 30 with respect to the engagement housing member 20 and/or the base member 50. The connecting element 40 may include a cylindrical flange portion that secures the engagement element with at least one of the engagement housing member and/or base member. The cylindrical flange portion may provide for the rotation of the engagement element with respect to at least one of the engagement housing member and/or base member. According to some aspects, the method may include placing the mobile device engagement apparatus in an optimal viewing position on a surface, when the engagement element 30 and/or the mobile device engagement apparatus is configured in the operating configuration.

The foregoing description comprises illustrative embodiments. Having thus described example embodiments, it should be noted by those skilled in the art that the within disclosures are example only, and that various other alternatives, adaptations, and modifications may be made within the scope of the present disclosure. Merely listing or numbering the steps of a method in a certain order does not constitute any limitation on the order of the steps of that method. Many modifications and other embodiments will come to mind to one skilled in the art to which this disclosure pertains having the benefit of the teachings presented in the foregoing descriptions and the associated drawings. Although specific terms may be employed herein, they are used in a generic and descriptive sense only and not for purposes of limitation. Accordingly, the present disclosure is not limited to the specific embodiments illustrated herein, but is limited only by the following claims.

1. A mobile device engagement apparatus, the apparatus comprising:
an engagement housing member, wherein the engagement housing member extends from a first end to an opposing second end, the engagement housing member defining an engagement element cavity;
an engagement element extending from a first engagement element end to an opposing second engagement element end, the engagement element being moveable between at least one of a stored configuration, an operating configuration, and a secured configuration; and
a connecting element configured to securely engage the engagement housing member and the engagement element with another, the connecting element further configured to provide for rotation of the engagement element with respect to the engagement housing member.

2. The apparatus of claim 1, wherein the engagement element further comprises an engagement member and a protective member.

3. The apparatus of claim 1, wherein the engagement element further comprises a securing apparatus, the securing apparatus being configured to retain the engagement element in the secured configuration.

4. The apparatus of claim 3, wherein the engagement element is configured to provide an opposing force biasing the engagement element to the operating configuration as the engagement element is manipulated from the operating configuration to the secured configuration.

5. The apparatus of claim 4, wherein the opposing force further provides for retaining the engagement element in the secured configuration when the securing apparatus is engaged.

6. The apparatus of claim 1 further comprising a base member extending from a first base end to an opposing second base end, wherein the base member is further configured to operably engage the engagement housing member, the base member and the engagement housing member configured to move with respect to one another, wherein the base member is further configured to securely engage a mobile device;

7. The apparatus of claim 6, wherein the engagement housing member further comprises a base engagement element, the base engagement element extending from the engagement housing member, wherein the base member further defines a base channel configured to reciprocally engage the base engagement element.

8. The apparatus of claim 6, wherein the engagement housing member is configured to move with respect to the base member along a longitudinal axis that extends from the first end to the opposing second end of the mobile device engagement apparatus.

9. The apparatus of claim 1 further comprising a magnetic element configured to removably attach the mobile device engagement apparatus to a magnetic surface.

10. The apparatus of claim 1, wherein the engagement housing member further defines a top surface, wherein the top surface of the engagement housing member comprises a material configured to operably engage a surface so as to affix the mobile device engagement apparatus to the surface.

11. A method of engaging a mobile device engagement apparatus, the method comprising:
providing a force to an engagement element of the mobile device engagement apparatus so as to transform the mobile device engagement apparatus from a stored configuration to an operating configuration, the apparatus including:
an engagement housing member, wherein the engagement housing member extends from a first end to an opposing second end, the engagement housing member defining an engagement element cavity;
an engagement element extending from a first engagement element end to an opposing second engagement element end, the engagement element being moveable between at least one of the stored configuration, the operating configuration, and a secured configuration; and
a connecting element configured to securely engage the engagement housing member and the engagement element with another, the connecting element further configured to provide for the rotation of the engagement element with respect to the engagement housing member;
providing a first force to the first engagement element end and an opposing second force to the opposing second engagement element end so as to bias the first engagement element end and the opposing second engagement element end towards one another; and
engaging a securing apparatus of the engagement element so as to position the mobile device engagement apparatus in the secured configuration, the securing apparatus being configured to retain the engagement element in the secured configuration.
